(19) United States
(12) Patent Application Publication
(10) Pub. No.: US 2026/0096398 A1
(43) Pub. Date: Apr. 2, 2026

(54) DESIGN OF VOLTAGE CONTRAST STRUCTURES AND METHODOLOGY TO DETECT GATE VIA TO CONTACT SHORTS

(71) Applicant: Intel Corporation, Santa Clara, CA (US)

(72) Inventors: Sairam Subramanian, Portland, OR (US); Dipto Thakurta, Portland, OR (US); Xiao Wen, Hillsboro, OR (US)

(73) Assignee: Intel Corporation, Santa Clara, CA (US)

(21) Appl. No.: 18/900,324

(22) Filed: Sep. 27, 2024

(51) Int. Cl. H01L 21/66

(52) U.S. Cl. CPC H10P 74/273; H10P 74/203

(57) ABSTRACT

Integrated circuit (IC) devices having gate vias adjacent metal contacts over source and drain bodies in transistors.

An IC device may include a test structure having a pair of electrodes, a floating electrode and a gate electrode in a dummy transistor, both the floating and gate electrodes adjacent a metal line grounded by the dummy transistor. Voltage contrast analysis (e.g., with e-beam scanning) of a gate via on the floating electrode may be used to detect a via short to the metal line. The test structure may include vast arrays of the electrode pairs.

### BACKGROUND

The difficulties of inline detection of buried or marginal device-layer defects during integrated circuit (IC) fabrication (for example, by wafer-level test or inspection) may delay the discovery of faults (even from wide-spread process issues) and, therefore, cures for the faults. Defect detection by yield and failure analyses (or other end of line signals) requires significant manufacturing delay, during which time no solutions to (or corrections of) process problems can be determined (or implemented). For example, vias may short together underlying structures (such as transistor gates and sources or drains), and an overlying dielectric layer may prevent detection of the buried metal connection by visual inspection, even automated optical scans. Test of such early formed (e.g., tiny and numerous) structures may be precluded until further connections are made between terminals into a testable (e.g., contactable) assembly. But these further connections may hide the defects until later, when still further connections allow testing of full functionality.

Process-monitor wafers may be taken out of line and evaluated, but not without further delay. Additionally, such evaluations are typically destructive (resulting in the discarding of valuable product) and (even if successful) difficult to correlate to more-sustainable detection methods (such as test).

New techniques and structures are needed to improve early detection of device faults specifically and front-end-of-line (FEOL) process issues generally. This early detection may enable process development and improvements that would otherwise be delayed or impossible.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate plan views of an integrated circuit (IC) device having electrically grounded metal lines adjacent electrode pairs and dummy transistor structures in a test structure, in accordance with some embodiments;

FIGS. 2A and 2B illustrate cross-sectional profile views of an IC device having electrically grounded metal lines adjacent dummy transistor structures and gate vias on floating electrodes in a test structure, in accordance with some embodiments;

FIG. 3 illustrates plan views of an IC device having a large array of transistor structures and electrode pairs in a test structure, in accordance with some embodiments;

FIG. 4 is a flow chart of methods for detecting defects in IC devices, for example, early in a manufacturing process, in accordance with some embodiments;

FIG. 5 illustrates a diagram of an example data server machine employing an IC device having Voltage Contrast (VC) test arrays, in accordance with some embodiments; and

FIG. 6 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed to improve defect detection early in fabrication of integrated circuit (IC) devices, for example, to detect gate-via shorts to adjacent trench contacts.

The structures and methods described herein enable the early discovery of gate electrodes shorting to electrical ground, e.g., in field-effect transistors (FETs), such as metal-oxide-semiconductor (MOS) FETs. Test structures are disclosed that provide exposed via tops to reveal ground shorts by inline scanning, including early in a manufacturing process, such as during front-end-of-line (FEOL) processing. Vast arrays of the test structures (for example, with millions of electrode pairs and dummy transistors) may be employed across IC dies and/or wafers to develop troubleshooting signals for even low defect densities. The test arrays may be deployed wherever sufficient space is available (e.g., as or in place of dummy fill) and/or where process issues are known or expected to be most problematic.

The described test structures facilitate analysis by voltage contrast (VC) and similar techniques, e.g., that generate test (e.g., imaging) data without requiring contact probing of numerous and miniscule test features. Voltage contrast analysis may be utilized in concert with beam-scanning methodologies to quickly and effectively highlight individual failures, as well as areas having high concentrations of defects.

An example fault profile well-suited to this technique is that of gate-drain or gate-source shorts caused by gate vias that contact source or drain contacts under a dielectric layer over a transistor. The vias are typically formed through a dielectric layer already covering the to-be-contacted structure, and a misalignment at a via bottom (e.g., contacting a source or drain contact instead of, or in addition to, a gate electrode) may be obscured and not visually detectable at a via top. The beam-scanning and VC methodologies may be exploited by designing and deploying dense arrays of test structures with gate vias on floating gates (e.g., gates on isolation, with only high-impedance paths to ground) next to trench contacts and/or contact lines on diffusions (e.g., semiconductor segments that provide low-impedance ground paths). In some embodiments, for example, provided a certain stimulus (such as a particular electrical field and scanned beam), a gate via on a floating (e.g., not grounded) gate electrode will appear dark under VC, and a grounded gate via (e.g., shorting to a trench-contact line, grounded through a source or drain epi) will appear bright.

Test structures corresponding to this fault profile are described herein, for example, a dummy transistor with a source or drain contact connected to a metal line extending adjacent a dummy gate electrode. The dummy transistor may be fully formed (e.g., including source and drain contacts), but without wired connections to power supplies (and, in many embodiments, including a gate electrode, but not a gate via). The metal line may be electrically grounded (through the source or drain and corresponding contact) by the transistor diffusion, whether a fin in a FinFET or stack of nanoribbons in a RibbonFET. The dummy (e.g., floating) gate electrode may be a part of a matching electrode pair with the gate electrode in the dummy transistor. For example, the floating gate may share similarities with the gate electrode in the dummy transistor (e.g., being laterally aligned with the gate electrodes in a grid or array and being of the same materials), but (in many embodiments) the floating gate may include (or be contacted by a gate via).

The described structures and techniques may provide inline detection of difficult problems and may save weeks of troubleshooting and yield-analysis time, e.g., by not having to run potential wafer test skews to end of line. Notably, the VC test is non-destructive and can be run on production wafers to end of line, thereby minimizing cost and establishing correlations to known yield signals (such as other wafer test results) at end of line.

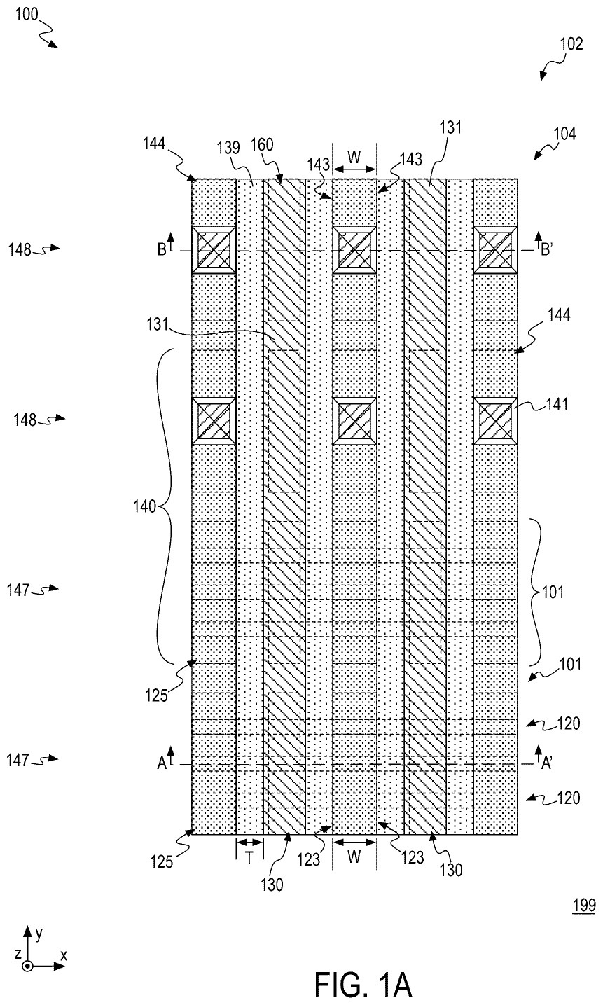

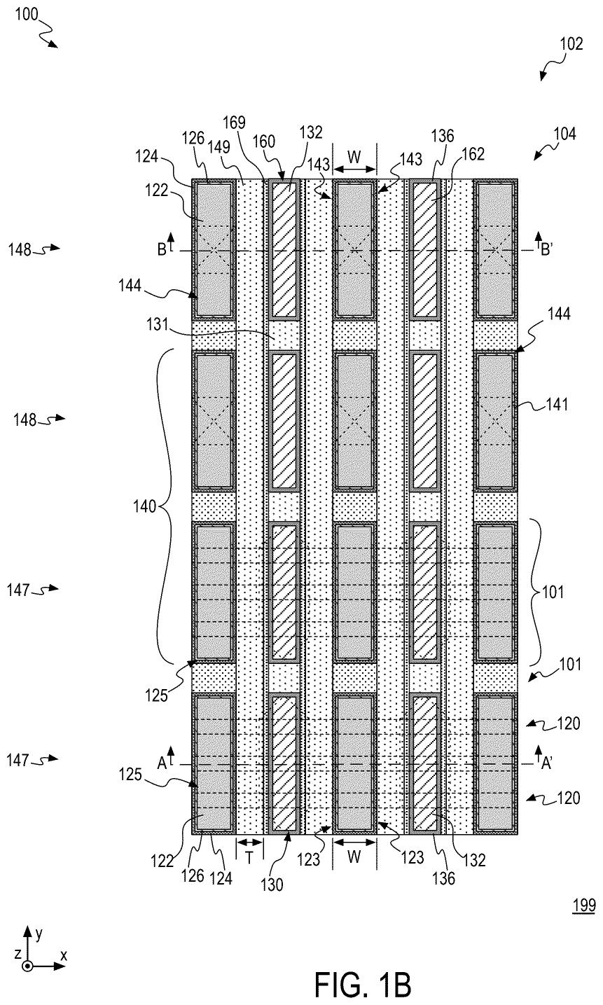

FIGS. 1A and 1B illustrate plan views of an IC device 100 having electrically grounded metal lines 131 adjacent electrode pairs 140 and dummy transistor structures 101 in a test structure 102, in accordance with some embodiments. FIGS. 1A and 1B show similar plan views of test structure 102, but at different levels, e.g., for illustrative purposes. FIG. 1A shows a level above the level illustrated at FIG. 1B. Structures at other levels may be shown with dotted or dashed outlines. For example, gate vias 141 in the top level of FIG. 1A have solid borders, but the floating electrodes 144 that vias 141 touch down on are illustrated with dashed borders (under dielectric layer 139). Gate vias 141 have dotted borders in FIG. 1B, where floating electrodes 144 have solid borders. Metal lines 131 have solid borders in FIG. 1A, but the metal contacts 130 have dashed borders under lines 131.

FIG. 1A shows test structure 102 in apparatus or device 100. Device 100 and test structure 102 include multiple electrode pairs 140, one or more electrically grounded metal lines 131 near electrode pairs 140, multiple transistor structures 101, and multiple vias 141. Metal lines 131 are on, and in contact with, metal contacts 130. Device 100 and test structure 102 may include, and metal lines 131 may be on, and in contact with, metal structures 160, which may be under lines 131 away from transistor structures 101, e.g., in place of contacts 130. Metal lines 131 are in dielectric layer 139 (e.g., with a top surface of each of lines 131 exposed, available for VC analysis). Metal lines 131 are electrically grounded through metal contacts 130 and transistor structures 101 to substrate 199. Lines 131 may provide dark (e.g., grounded) features for VC analysis of test structure 102.

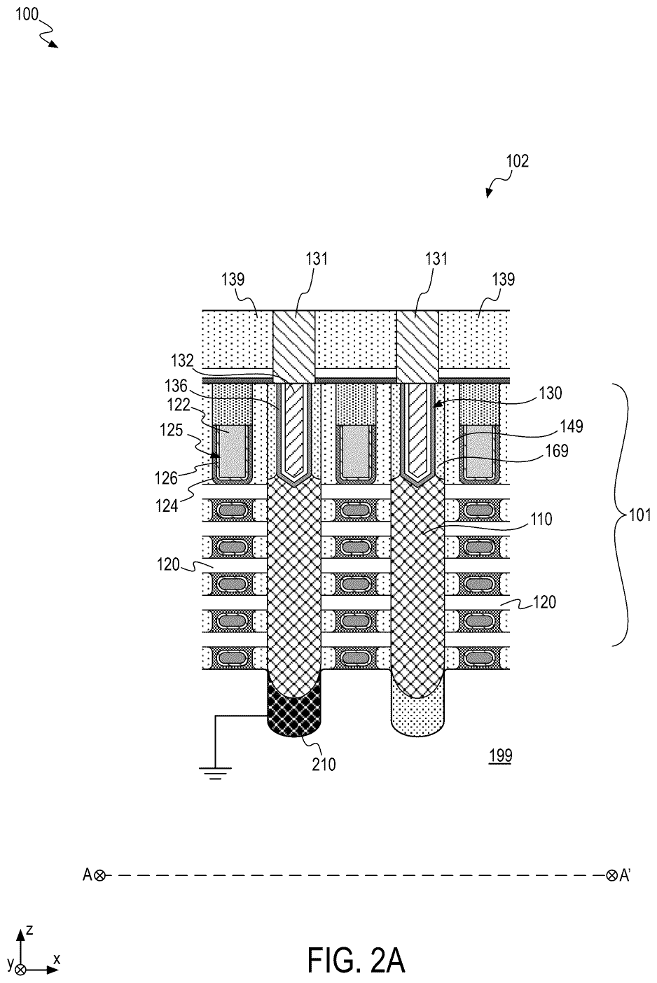

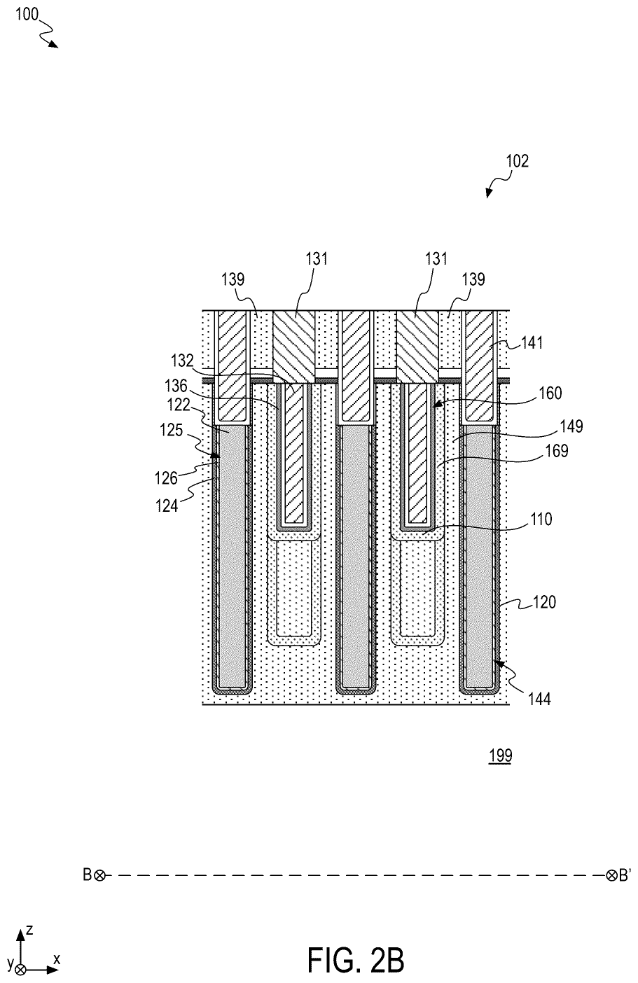

Each transistor structure 101 includes a gate electrode 125, a pair of source and drain bodies (under metal contacts 130; shown in FIGS. 1B and 2A), and contacts 130 on the source and drain bodies. Transistor structures 101 may be dummy transistor structures 101, for example, fully formed, but without connections to power supplies. For example, the source and drain bodies (and metal contacts 130) are at electrical ground. In many embodiments, gate electrode 125 is also not connected to any power sources, e.g., without any gate vias 141 or contacts. Gate electrodes 125 are over channel regions 120 and may be metal gate electrodes 125, including one or more gate metals on a gate dielectric between the gate metal(s) and channel region 120. Channel region 120 may be any suitable structure or region 120, such as a fin or stack of nanoribbons of semiconductor material.

Each electrode pair 140 includes a gate electrode 125 and an electrically floating electrode 144. Electrode 144 is electrically floating, a metal electrode 144 electrically isolated from adjacent structures by dielectric materials (such as dielectric layer 139). Electrically floating electrode 144 has only high-impedance paths to ground. Floating electrode 144 may share similarities with gate electrode 125, e.g., to provide a structure similar to, or representative of, electrode 125 for test purposes, but may be separate from any transistor structure 101. Making floating electrode 144 like transistor gate electrode 125 may enable representative test results (e.g., defect signals) from VC analysis, but keeping floating electrode 144 separate from any transistor structure 101 may ensure any defect signals are only for desired fault types (e.g., shorts between gate vias 141 and contact lines 131) and not due to transistor fabrication issues. Advantageously, electrodes 125, 144 have similar dimensions and include (for example, are formed from) the same materials. In many embodiments, dummy or floating electrode 144 includes the same one or more gate metals and gate dielectric as gate electrode 125 (of transistor structure 101).

Electrodes 125, 144 of electrode pair 140 may also have similar dimensions and be similarly oriented (e.g., with metal lines 131) in the grid of test array 104. Again, these similarities between electrodes 125, 144 may help ensure that defect signals from electrodes 144 are representative for actual transistor structures 101 and gate electrodes 125 (e.g., elsewhere in device 100). Electrically grounded metal lines 131, gate electrodes 125, and electrically floating electrodes 144 extend in the y-directions. Electrode pairs 140 are aligned in an array of orthogonal columns and rows 147, 148. Gate electrodes 125 are in first rows 147, and electrodes 144 are in second row 148 (e.g., with the first and second rows 147, 148 extending in the y-directions). Electrodes 125, 144 may have similar dimensions and aligned edges or sidewalls 123, 143 in array 104. Gate electrodes 125 have sidewalls 123 extending in the y-directions and separated by a width W measured in the x-directions. Floating electrodes 144 have sidewalls 143 extending in the y-directions separated by the same width W measured in the x-directions (equal to width W of electrodes 125). Both sidewalls 123 of each of electrodes 125 are aligned (e.g., coplanar) with both sidewalls 143 of each of electrodes 144.

Floating electrodes 144 may include vias 141. Vias 141 are on (or part of), and in contact with, electrically floating electrodes 144. Vias 141 extend through dielectric layer 139 (e.g., with a top surface of each of vias 141 exposed, available for VC analysis) and contact an upper surface of floating electrodes 144 (e.g., at a bottom surface of each of vias 141). Vias 141 are adjacent metal lines 131 in layer 139. In many embodiments, vias 141 are nearer to an adjacent line 131 than the via 141 is wide, having a width W of via 141 greater than a thickness T of dielectric layer 139 between vias 141 and the adjacent metal line 131.

Vias 141 that are fabricated as desired (for example, centered over and contacting floating electrodes 144 through dielectric layer 139) do not contact (e.g., are not shorted to) grounded metal lines 131. These vias 141, electrically floating with electrodes 144, may be relatively dark under VC, while faulty vias 141 that short to lines 131 (and electrical ground) through layer 139 may show up brighter under VC, which may be detected as a defect. Vias 141 (and metal lines 131 and dielectric layer 139) may be exposed at a VC operation (e.g., during a fabrication process) but may later be covered by subsequently fabricated layers (e.g., of dielectric material with metal interconnects extending laterally and vertically through the dielectric).

Substrate 199 may include any suitable material or materials. In some examples, substrate 199 may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. In many embodiments, substrate 199 includes a semiconductor material under regions 120 and source and drain bodies, and channel regions 120 are of the same semiconductor material. Substrate 199 may also include other semiconductor materials, metals, dielectrics, dopants, and other materials commonly found in semiconductor substrates.

FIG. 1B illustrates test structure 102 in IC device 100, including multiple electrode pairs 140 (of electrodes 125, 144), electrically grounded metal contacts 130 (and metal or metallization structures 160) near electrode pairs 140, multiple transistor structures 101, and multiple vias 141 (e.g., over the level of FIG. 1B, shown as dashed or dotted). Metal contacts 130 are in transistor structures 101 (under, and in contact with, metal lines 131), adjacent gate electrodes 125. Metal structures 160 may be under (and in contact with) metal lines 131, adjacent floating electrodes 144. Metal structures 160 may be grounded by lines 131. Metal lines 131 are electrically grounded through metal contacts 130 and transistor structures 101 to substrate 199.

Again, floating electrodes 144 may be analogs of, and parts of pairs 140 with, gate electrodes 125. A dielectric material of dielectric layer 149 is between metal contact 130 and gate electrodes 125 and between metal contact 130 and floating electrodes 144. The dielectric material of dielectric layer 149 is between metal structures 160 (which are analogs of metal contacts 130) and gate electrodes 125 and between structures 160 and floating electrodes 144.

Floating electrodes 144 are further duplicates of, and parts of pairs 140 with, gate electrodes 125 due to the matching materials of electrodes 125, 144. Gate electrodes 125 are over channel region 120 and include a gate metal 122. A gate dielectric material 124 is on gate electrodes 125, between the metal 122 and channel region 120. Gate electrodes 125 may include a liner metal 126 on gate dielectric material 124, e.g., around metal 122. Floating electrodes 144 are not over any channel region 120, but electrodes 144 include metal 122. Dielectric material 124 is on electrodes 144, around metal 122. Floating electrodes 144 may include a liner metal 126 on dielectric material 124, e.g., around metal 122.

Metal structures 160 similarly imitate metal contacts 130, e.g., to replicate structures of and adjacent transistor structures 101. Metal contacts 130 include a metal 132 and (in some embodiments) a liner metal 136. A dielectric material of dielectric layer 169 is on both metal contacts 130 and structures 160, between metal 132 and electrodes 125, 144. Metallization structure 160 is between floating electrodes 144 (e.g., a first electrode 144 and an adjacent second electrode 144). Grounded metal lines 131 are on, and in contact with, metallization structures 160. Metallization structures 160 include metal 132. In at least some embodiments that contacts 130 include liner metal 136, metallization structures 160 include liner metal 136.

FIGS. 2A and 2B illustrate cross-sectional profile views of an IC device 100 having electrically grounded metal lines 131 adjacent dummy transistor structures 101 and gate vias 141 on floating electrodes 144 in test structure 102, in accordance with some embodiments. FIGS. 2A and 2B show some of the similarities of electrodes 125, 144, etc., but in profile views.

FIG. 2A illustrates metal contacts 130 in transistor structures 101 (under, and in contact with, metal lines 131), adjacent gate electrodes 125. Metal lines 131 are electrically grounded through metal contacts 130 and transistor structures 101 (e.g., source and drain bodies 110) to substrate 199.

Drain and source bodies 110 are electrically and physically coupled to opposite ends of channel regions 120. Source and drain bodies 110 are impurity doped bodies, e.g., regions of semiconductor material doped with one or more electrically active impurities and having increased charge-carrier availabilities and associated conductivities. Drain and source bodies 110 may include a predominant semiconductor material, and one or more n-dopants (e.g., donor impurities, such as phosphorus, arsenic, or antimony) or p-type impurities (e.g., acceptor impurities, such as boron or aluminum). Other dopant materials may be used. In many embodiments, transistor structures 101 are PMOS FET structures 101 (e.g., grounded to substrate 199), and bodies 110 includes p-type, acceptor dopants.

Source and drain bodies 110 may be formed by any suitable means. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source and drain bodies 110 may be polycrystalline or substantially monocrystalline, e.g., having long-range order at least adjacent ends of channel regions 120 and merging or joining into a unitary body with few grain boundaries.

A dielectric material of dielectric layer 149 is between metal contact 130 and gate electrodes 125. Gate electrodes 125 are over channel region 120 and include gate metal 122. Gate dielectric material 124 is on gate electrodes 125, between the metal 122 and channel region 120. Gate electrodes 125 may include a liner metal 126 on gate dielectric material 124, e.g., around metal 122. Floating electrodes 144 may have similar constructions, as described at FIG. 2B.

Transistor structures 101 and channel regions 120 include stacks of nanoribbons, and gate electrodes 125 are over the stacks of nanoribbons.

Metal contacts 130 include metal 132 and (in some embodiments) a liner metal 136. A dielectric material of dielectric layer 169 is on both metal contacts 130, between metal 132 and electrodes 125. Metallization structure 160 may have similar constructions, as described at FIG. 2B.

Some of transistor structures 101 include tap 210, which ensures bodies 110 (and metal contacts 130 and lines 131) are well grounded. Grounded metal lines 131 are electrically grounded through substrate tap 210 below line 131. In some embodiments, metal lines 131 are electrically grounded to substrate 199 through a tap 210 below line 131 and adjacent structure 101. In some embodiments, metal lines 131 are electrically grounded through a diffusion or well in substrate 199 below line 131. In some embodiments, metal lines 131 are electrically grounded through to substrate 199 through channel region 120 below line 131. In some such embodiments, channel region 120 is a fin of semiconductor material in a FinFET structure 101.

FIG. 2B illustrates gate vias 141 on floating electrodes 144 and adjacent metallization structures 160 in test structure 102. Vias 141 are between electrically grounded metal lines 131.

Metal structures 160 are under and in contact with metal lines 131, adjacent floating electrodes 144. Metal structures 160 are grounded by lines 131. Metal structures 160 are analogs of metal contacts 130, e.g., replicating transistor structures 101. Metal structures 160 include metal 132 and (in some embodiments) a liner metal 136. A dielectric material of dielectric layer 169 is on both metal structures 160, between metal 132 and electrodes 125, 144. Metallization structure 160 is between floating electrodes 144 (e.g., a first electrode 144 and an adjacent second electrode 144).

Floating electrodes 144 are parts of pairs 140 with gate electrodes 125. A dielectric material of dielectric layer 149 is between metal structures 160 and electrodes 144. Floating electrodes 144 are not over any channel region 120, but electrodes 144 include metal 122. Dielectric material 124 is on electrodes 144, around metal 122. Floating electrodes 144 include liner metal 126 on dielectric material 124, e.g., around metal 122.

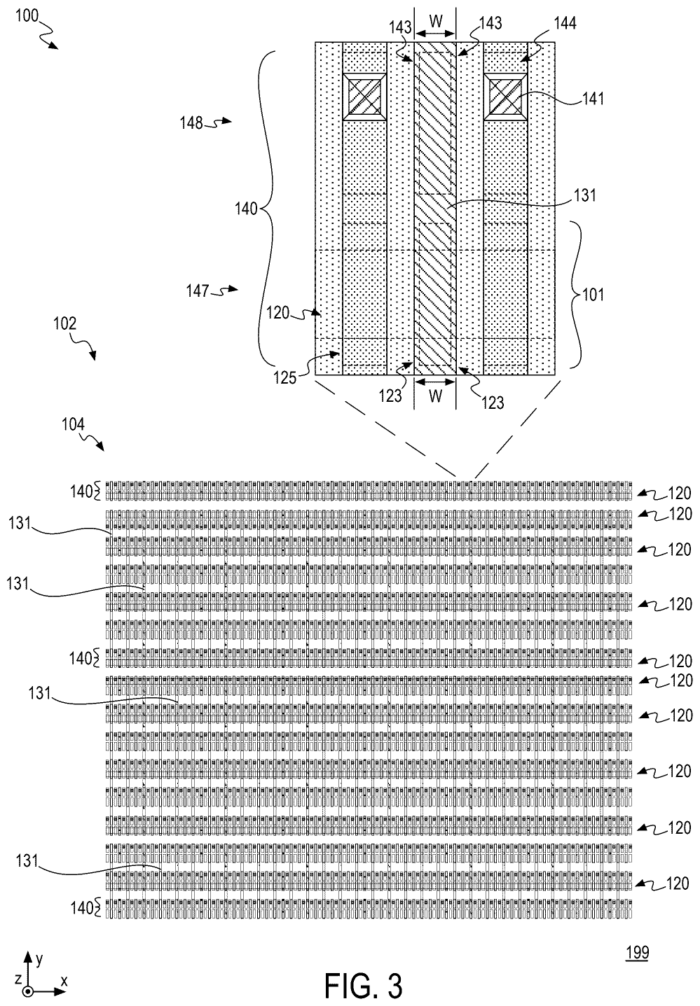

FIG. 3 illustrates plan views of IC device 100 having large array 104 of transistor structures 101 and electrode pairs 140 in test structure 102, in accordance with some embodiments. In many embodiments, test structure 102 and array 104 includes more than ten thousand vias 141 on more than ten thousand electrically floating electrodes 144. In some embodiments, test structure 102 and array 104 includes more than a million vias 141 on more than a million electrically floating electrodes 144. Large arrays 104 may include many channel regions 120 (e.g., of fins in FinFET structures 101 or nanoribbons in RibbonFET structures 101) and many metal lines 131. Lines 131 may be grounded as necessary by one or multiple substrate taps.

Electrically grounded metal lines 131, gate electrodes 125, and electrically floating electrodes 144 extend in the y-directions. Electrode pairs 140 are aligned in array 104 of orthogonal columns and rows 147, 148. Gate electrodes 125 are in first rows 147, electrodes 144 are in second rows 148, and both of rows 147, 148 extend in the x-directions. Grounded lines 131 may extend in y-directions between and beyond multiple rows 147, 148 of electrodes 125, 144 (as shown in FIG. 3). Gate electrodes 125 have sidewalls 123 extending in the y-directions and separated by width W in the x-directions. Floating electrodes 144 have sidewalls 143 extending in the y-directions separated by the same width W in the x-directions (equal to width W of electrodes 125). Sidewalls 123 of electrodes 125 are aligned (e.g., coplanar) with sidewalls 143 of electrodes 144.

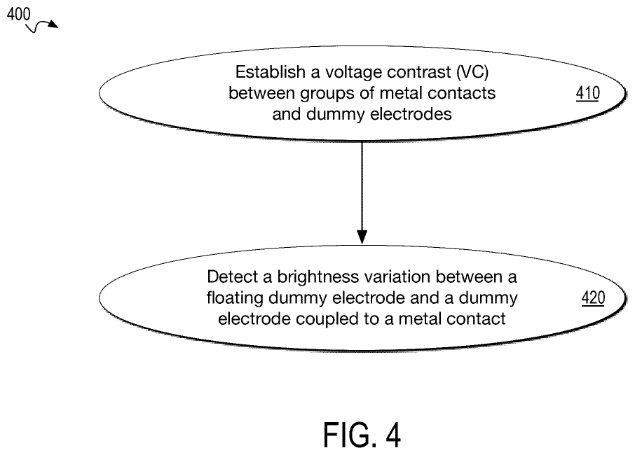

FIG. 4 is a flow chart of methods 400 for detecting defects in IC devices, for example, early in a manufacturing process (e.g., at FEOL), in accordance with some embodiments. Methods 400 include operations 410 and 420. Additional operations may be included. FIG. 4 shows an example sequence, but the operations can be done in other orders as well, and some operations may be omitted. Some operations can also be performed multiple times before other operations are performed. Some operations may be included within other operations so that the number of operations illustrated FIG. 4 is not a limitation of the methods 400.

Methods 400 begin at operation 410 with establishing a voltage contrast between test electrodes. In many embodiments, a voltage contrast is established between a group of metal contacts and a group of dummy electrodes. The metal contacts may be included in (e.g., as parts of) a group of transistor structures. For example, the metal contacts may be on source and drain bodies. The transistor structures may each include a gate electrode between the source and drain bodies. The transistor structures may each include one or more dielectric layers between the metal contacts and the gate electrodes and between the metal contacts and the dummy electrodes. The dummy electrodes may be aligned with the gate electrodes, for example, to provide structures analogous to those fabricated elsewhere in the device, e.g., outside of the test structures. The transistor structures may be much as described of structures 101, e.g., at least at FIG. 1A-2B, including gate electrodes 125. The dummy electrodes may be much as described of floating electrodes 144, e.g., at least at FIG. 1A-2B, including vias 141. Vias (e.g., gate vias) may extend through a dielectric layer over the floating, dummy electrodes. The vias may contact the dummy electrodes on a lower end of each of the vias, and an upper end of each of the vias may be exposed, available for VC analysis. The transistor structures and dummy electrodes may be in an array of more than a million dummy electrodes and more than a million transistor structures.

The voltage contrast may be established between the metal contacts and dummy electrodes by stimulating the array of vias with a beam of electrons or ions. For example, an e-beam (e.g., electron beam) may be scanned over the test structure array without the need to contact any test structures or features. The metal contacts may be electrically grounded, for example, by grounding a substrate (e.g., test wafer) and by grounding the metal contacts to the substrate ground through a semiconductor diffusion area of the substrate. In some embodiments, the metal contacts are grounded through source and drain epi and/or a p-type tap into a device substrate.

The scanning of the, e.g., e-beam over the array of test features (e.g., floating or dummy electrodes) may develop a VC where no (or a low) voltage is on grounded (or nearly grounded) structures, and a significant voltage may be developed on floating electrodes. Floating electrodes and vias may have a very different developed voltage than a grounded via (e.g., coupled to ground through a shorted contact). Different voltage contrasts may be developed differently using different beam types, electric fields, etc.

Methods 400 continue at operation 420 with detecting a brightness variation between test features. In some embodiments, a brightness variation is detected between a floating dummy electrode and a dummy electrode coupled to a metal contact by a metal structure (such as a via) shorting through the dielectric layer(s) over and/or between the contact and dummy electrode.

In many embodiments, the brightness variation is detected between the floating dummy electrode and the coupled (e.g., grounded) dummy electrode by detecting the brightness variation at a via on the coupled (e.g., grounded) dummy electrode. A shorted, grounded via on what should be a floating dummy electrode (but is no longer electrically floating) may appear bright while most vias (e.g., electrically floating vias) may appear darker. In this way, the defect (e.g. a via short through the dielectric layer separating the electrode from the metal contact and/or metal line) may be detected before much of the wafer (e.g., front-side interconnect layers) is completed. Appropriate actions (such as scrapping or process improvement) may be taken following any defect discovery. These actions may be more beneficial given the early and non-destructive detection of the defect(s) by the VC method.

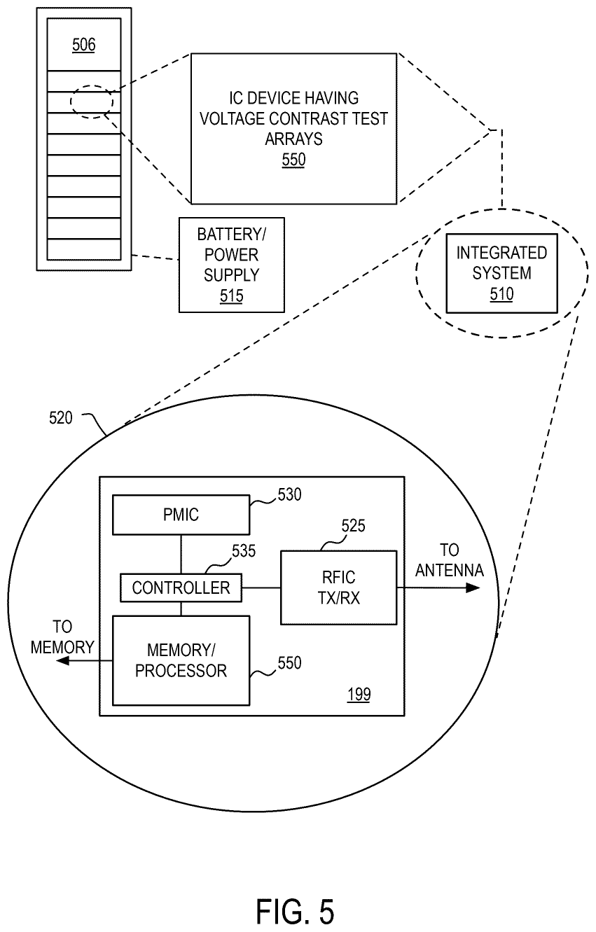

FIG. 5 illustrates a diagram of an example data server machine 506 employing an IC device having VC test arrays, in accordance with some embodiments. Server machine 506 may be any commercial server, for example, including any number of high-performance computing platforms disposed within a rack and networked together for electronic data processing, which in the exemplary embodiment includes one or more devices 550 having VC test arrays.

Also as shown, server machine 506 includes a battery and/or power supply 515 to provide power to devices 550, and to provide, in some embodiments, power delivery functions such as power regulation. Devices 550 may be deployed as part of a package-level integrated system 510. Integrated system 510 is further illustrated in the expanded view 520. In the exemplary embodiment, devices 550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 550 is a microprocessor including a static RAM (SRAM) cache memory. As shown, device 550 may be an IC device having VC test arrays, as discussed herein. Device 550 may be further coupled to (e.g., communicatively coupled to) a board, an interposer, or other substrate 199 along with, one or more of a power management IC (PMIC) 530, RF (wireless) IC (RFIC) 525 including a wideband RF (wireless) transmitter and/or receiver (TX/RX) (e.g., including a digital baseband and an analog front end module further includes a power amplifier on a transmit path and a low noise amplifier on a receive path), and a controller 535 thereof. In some embodiments, RFIC 525, PMIC 530, controller 535, and device 550 include having VC test arrays.

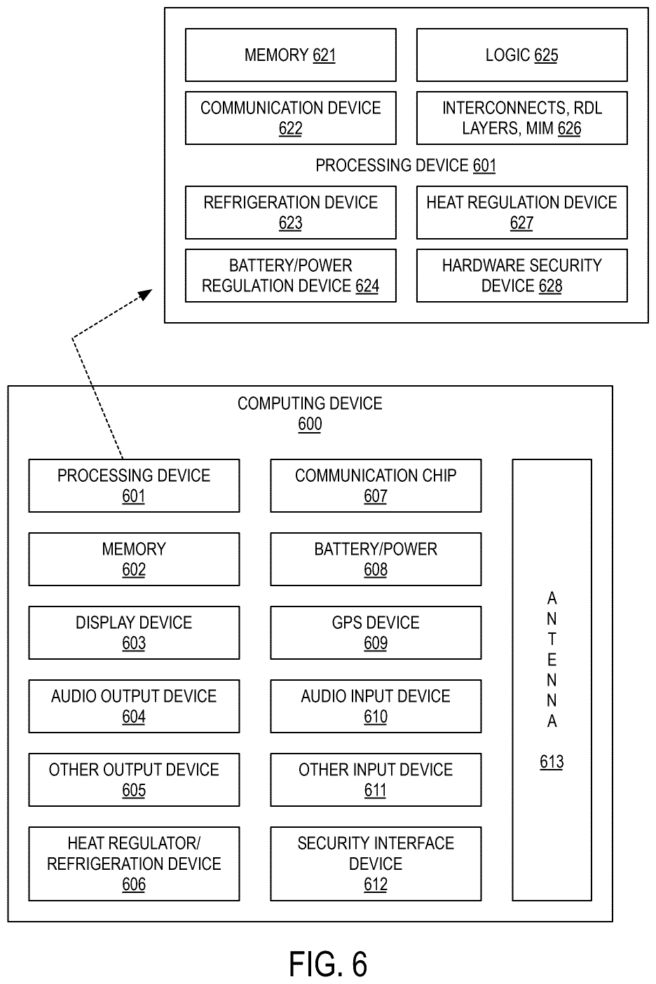

FIG. 6 is a block diagram of an example computing device 600, in accordance with some embodiments. For example, one or more components of computing device 600 may include any of the devices or structures discussed herein. A number of components are illustrated in FIG. 6 as being included in computing device 600, but any one or more of these components may be omitted or duplicated, as suitable for the application. In some embodiments, some or all of the components included in computing device 600 may be attached to one or more printed circuit boards (e.g., a motherboard). In some embodiments, various ones of these components may be fabricated onto a single system-on-a-chip (SoC) die. Additionally, in various embodiments, computing device 600 may not include one or more of the components illustrated in FIG. 6, but computing device 600 may include interface circuitry for coupling to the one or more components. For example, computing device 600 may not include a display device 603, but may include display device interface circuitry (e.g., a connector and driver circuitry) to which display device 603 may be coupled. In another set of examples, computing device 600 may not include an audio output device 604, other output device 605, global positioning system (GPS) device 609, audio input device 610, or other input device 611, but may include audio output device interface circuitry, other output device interface circuitry, GPS device interface circuitry, audio input device interface circuitry, audio input device interface circuitry, to which audio output device 604, other output device 605, GPS device 609, audio input device 610, or other input device 611 may be coupled.

Computing device 600 may include a processing device 601 (e.g., one or more processing devices). As used herein, the term “processing device” or “processor” indicates a device that processes electronic data from registers and/or memory to transform that electronic data into other electronic data that may be stored in registers and/or memory. Processing device 601 may include a memory 621, a communication device 622, a refrigeration device 623, a battery/power regulation device 624, logic 625, interconnects 626 (i.e., optionally including redistribution layers (RDL) or metal-insulator-metal (MIM) devices), a heat regulation device 627, and a hardware security device 628.

Processing device 601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 600 may include a memory 602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 602 includes memory that shares a die with processing device 601. This memory may be used as cache memory and may include embedded dynamic random-access memory (eDRAM) or spin transfer torque magnetic random-access memory (STT-MRAM).

Computing device 600 may include a heat regulation/refrigeration device 606. Heat regulation/refrigeration device 606 may maintain processing device 601 (and/or other components of computing device 600) at a predetermined low temperature during operation.

In some embodiments, computing device 600 may include a communication chip 607 (e.g., one or more communication chips). For example, the communication chip 607 may be configured for managing wireless communications for the transfer of data to and from computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 607 may operate in accordance with other wireless protocols in other embodiments. Computing device 600 may include an antenna 613 to facilitate wireless communications and/or to receive other wireless communications (such as AM or FM radio transmissions).

In some embodiments, communication chip 607 may manage wired communications, such as electrical, optical, or any other suitable communication protocols (e.g., the Ethernet). As noted above, communication chip 607 may include multiple communication chips. For instance, a first communication chip 607 may be dedicated to shorter-range wireless communications such as Wi-Fi or Bluetooth, and a second communication chip 607 may be dedicated to longer-range wireless communications such as GPS, EDGE, GPRS, CDMA, WiMAX, LTE, EV-DO, or others. In some embodiments, a first communication chip 607 may be dedicated to wireless communications, and a second communication chip 607 may be dedicated to wired communications.

Computing device 600 may include battery/power circuitry 608. Battery/power circuitry 608 may include one or more energy storage devices (e.g., batteries or capacitors) and/or circuitry for coupling components of computing device 600 to an energy source separate from computing device 600 (e.g., AC line power).

Computing device 600 may include a display device 603 (or corresponding interface circuitry, as discussed above). Display device 603 may include any visual indicators, such as a heads-up display, a computer monitor, a projector, a touchscreen display, a liquid crystal display (LCD), a light-emitting diode display, or a flat panel display, for example.

Computing device 600 may include an audio output device 604 (or corresponding interface circuitry, as discussed above). Audio output device 604 may include any device that generates an audible indicator, such as speakers, headsets, or earbuds, for example.

Computing device 600 may include an audio input device 610 (or corresponding interface circuitry, as discussed above). Audio input device 610 may include any device that generates a signal representative of a sound, such as microphones, microphone arrays, or digital instruments (e.g., instruments having a musical instrument digital interface (MIDI) output).

Computing device 600 may include a GPS device 609 (or corresponding interface circuitry, as discussed above). GPS device 609 may be in communication with a satellite-based system and may receive a location of computing device 600, as known in the art.

Computing device 600 may include other output device 605 (or corresponding interface circuitry, as discussed above). Examples of the other output device 605 may include an audio codec, a video codec, a printer, a wired or wireless transmitter for providing information to other devices, or an additional storage device.

Computing device 600 may include other input device 611 (or corresponding interface circuitry, as discussed above). Examples of the other input device 611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 600 may include a security interface device 612. Security interface device 612 may include any device that provides security measures for computing device 600 such as intrusion detection, biometric validation, security encode or decode, access list management, malware detection, or spyware detection.

Computing device 600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIG. 1A-6. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a plurality of electrode pairs, each electrode pair including a gate electrode and an electrically floating electrode, a plurality of vias on, and in contact with, the electrically floating electrodes, one or more electrically grounded metal lines adjacent to the plurality of electrode pairs, and a plurality of transistor structures, each transistor structure including one of the gate electrodes, a source or drain body, and a metal contact on the source or drain body, wherein a dielectric material is between the metal contact and corresponding ones of the gate electrodes and the electrically floating electrodes.

In one or more second embodiments, further to the first embodiments, the one of the gate electrodes is over a channel region and includes a metal, a gate dielectric material is on the one of the gate electrodes, between the metal and the channel region, a first of the electrically floating electrodes includes the metal, and the gate dielectric material is on the first of the electrically floating electrodes.

In one or more third embodiments, further to the first or second embodiments, a first of the one or more electrically grounded metal lines is in a dielectric layer, a first of the vias extends through the dielectric layer and contacts a first of the electrically floating electrodes, and the first of the vias has a width greater than a thickness of the dielectric layer between the first of the vias and the first of the one or more electrically grounded metal lines.

In one or more fourth embodiments, further to the first through third embodiments, a first of the one or more electrically grounded metal lines is on, and in contact with, a first of the metal contacts.

In one or more fifth embodiments, further to the first through fourth embodiments, the dielectric material is a first dielectric material, a first of the metal contacts includes a metal, a second dielectric material is on the first of the metal contacts, between the metal and the one of the gate electrodes, a metallization structure is between a first of the electrically floating electrodes and an adjacent second of the electrically floating electrodes, a first of the one or more electrically grounded metal lines on, and in contact with, the metallization structure, the metallization structure includes the metal, and the second dielectric material is on the metallization structure.

In one or more sixth embodiments, further to the first through fifth embodiments, one or more of the vias are between more than one of the one or more electrically grounded metal lines.

In one or more seventh embodiments, further to the first through sixth embodiments, the electrically grounded metal lines, the gate electrodes, and the electrically floating electrodes extend in a first direction, and the electrode pairs are aligned in an array of orthogonal columns and rows, the gate electrodes in a first row, the electrically floating electrodes in a second row, the first and second rows extending in a second direction orthogonal to the first direction.

In one or more eighth embodiments, further to the first through seventh embodiments, the one of the gate electrodes includes first and second sidewalls extending in the first direction separated by a first width measured in the second direction, a first of the electrically floating electrodes includes third and fourth sidewalls extending in the first direction separated by a second width measured in the second direction, and the first width is approximately equal to the second width, the first sidewall is substantially coplanar with the third sidewall, and the second sidewall is substantially coplanar with the fourth sidewall.

In one or more ninth embodiments, further to the first through eighth embodiments, the plurality of vias includes more than ten thousand vias on more than ten thousand electrically floating electrodes.

In one or more tenth embodiments, further to the first through ninth embodiments, each of the plurality of transistor structures includes a stack of nanoribbons, one of the gate electrodes over one of the stacks of nanoribbons.

In one or more eleventh embodiments, further to the first through tenth embodiments, a first of the one or more electrically grounded metal lines is electrically grounded through a substrate tap below the one or more electrically grounded metal lines.

In one or more twelfth embodiments, an apparatus includes a plurality of electrode pairs including a plurality of gate electrodes and a plurality of dummy electrodes, a plurality of vias on, and in contact with, the dummy electrodes, an electrically grounded metal line adjacent the electrode pairs, a dielectric material between the electrically grounded metal line and the gate electrodes and between the electrically grounded metal line and the dummy electrodes, and a plurality of transistor structures, each transistor structure including one of the gate electrodes, a source or drain body, and a metal contact on the source or drain body, wherein the metal contact is coupled with the electrically grounded metal line.

In one or more thirteenth embodiments, further to the twelfth embodiments, a first of the gate electrodes is over a channel region and includes a metal, a gate dielectric material is on the first of the gate electrodes, between the metal and the channel region, a first of the dummy electrodes includes the metal, and the gate dielectric material is on the first of the dummy electrodes.

In one or more fourteenth embodiments, further to the twelfth or thirteenth embodiments, the electrically grounded metal line is in a dielectric layer, a first of the vias extends through the dielectric layer and contacts the first of the dummy electrodes, and the first of the vias has a width greater than a thickness of the dielectric layer between the first of the vias and the electrically grounded metal line.

In one or more fifteenth embodiments, further to the twelfth through fourteenth embodiments, the plurality of vias includes more than ten thousand vias on more than ten thousand dummy electrodes.

In one or more sixteenth embodiments, a method includes establishing a voltage contrast between a plurality of metal contacts and a plurality of dummy electrodes, a plurality of transistor structures including the metal contacts on source and drain bodies, the plurality of transistor structures including gate electrodes between the source and drain bodies, one or more dielectric layers between the metal contacts and the gate electrodes and between the metal contacts and the dummy electrodes, the plurality of dummy electrodes aligned with the gate electrodes, and detecting a brightness variation between a coupled one of the dummy electrodes and a floating one of the dummy electrodes, the coupled one of the dummy electrodes coupled to an individual one of the metal contacts by a metal structure shorting through the dielectric layers.

In one or more seventeenth embodiments, further to the sixteenth embodiments, the establishing the voltage contrast between the plurality of metal contacts and the plurality of dummy electrodes includes stimulating a plurality of vias with a beam of electrons or ions.

In one or more eighteenth embodiments, further to the sixteenth or seventeenth embodiments, the establishing the voltage contrast between the plurality of metal contacts and the plurality of dummy electrodes includes grounding the plurality of metal contacts.

In one or more nineteenth embodiments, further to the sixteenth through eighteenth embodiments, the detecting the brightness variation between the coupled one of the dummy electrodes and the floating one of the dummy electrodes includes detecting the brightness variation at an individual one of the vias on the coupled one of the dummy electrodes.

In one or more twentieth embodiments, further to the sixteenth through nineteenth embodiments, the plurality of dummy electrodes includes more than a million dummy electrodes.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a plurality of electrode pairs, each electrode pair comprising a gate electrode and an electrically floating electrode;
a plurality of vias on, and in contact with, the electrically floating electrodes;
one or more electrically grounded metal lines adjacent to the plurality of electrode pairs; and
a plurality of transistor structures, each transistor structure comprising one of the gate electrodes, a source or drain body, and a metal contact on the source or drain body, wherein a dielectric material is between the metal contact and corresponding ones of the gate electrodes and the electrically floating electrodes.

2. The apparatus of claim 1, wherein:
the one of the gate electrodes is over a channel region and comprises a metal;
a gate dielectric material is on the one of the gate electrodes, between the metal and the channel region;
a first of the electrically floating electrodes comprises the metal; and
the gate dielectric material is on the first of the electrically floating electrodes.

3. The apparatus of claim 1, wherein:
a first of the one or more electrically grounded metal lines is in a dielectric layer;
a first of the vias extends through the dielectric layer and contacts a first of the electrically floating electrodes; and
the first of the vias has a width greater than a thickness of the dielectric layer between the first of the vias and the first of the one or more electrically grounded metal lines.

4. The apparatus of claim 1, wherein a first of the one or more electrically grounded metal lines is on, and in contact with, a first of the metal contacts.

5. The apparatus of claim 1, wherein:
the dielectric material is a first dielectric material;
a first of the metal contacts comprises a metal;
a second dielectric material is on the first of the metal contacts, between the metal and the one of the gate electrodes;
a metallization structure is between a first of the electrically floating electrodes and an adjacent second of the electrically floating electrodes, a first of the one or more electrically grounded metal lines on, and in contact with, the metallization structure;
the metallization structure comprises the metal; and
the second dielectric material is on the metallization structure.

6. The apparatus of claim 1, wherein one or more of the vias are between more than one of the one or more electrically grounded metal lines.

7. The apparatus of claim 1, wherein:
the electrically grounded metal lines, the gate electrodes, and the electrically floating electrodes extend in a first direction; and
the electrode pairs are aligned in an array of orthogonal columns and rows, the gate electrodes in a first row, the electrically floating electrodes in a second row, the first and second rows extending in a second direction orthogonal to the first direction.

8. The apparatus of claim 7, wherein:
the one of the gate electrodes comprises first and second sidewalls extending in the first direction separated by a first width measured in the second direction;
a first of the electrically floating electrodes comprises third and fourth sidewalls extending in the first direction separated by a second width measured in the second direction; and
the first width is approximately equal to the second width;
the first sidewall is substantially coplanar with the third sidewall; and
the second sidewall is substantially coplanar with the fourth sidewall.

9. The apparatus of claim 1, wherein the plurality of vias comprises more than ten thousand vias on more than ten thousand electrically floating electrodes.

10. The apparatus of claim 1, wherein each of the plurality of transistor structures comprises a stack of nanoribbons, one of the gate electrodes over one of the stacks of nanoribbons.

11. The apparatus of claim 1, wherein a first of the one or more electrically grounded metal lines is electrically grounded through a substrate tap below the one or more electrically grounded metal lines.

12. An apparatus, comprising:
a plurality of electrode pairs comprising a plurality of gate electrodes and a plurality of dummy electrodes;
a plurality of vias on, and in contact with, the dummy electrodes;
an electrically grounded metal line adjacent the electrode pairs;
a dielectric material between the electrically grounded metal line and the gate electrodes and between the electrically grounded metal line and the dummy electrodes; and
a plurality of transistor structures, each transistor structure comprising one of the gate electrodes, a source or drain body, and a metal contact on the source or drain body, wherein the metal contact is coupled with the electrically grounded metal line.

13. The apparatus of claim 12, wherein:
a first of the gate electrodes is over a channel region and comprises a metal;
a gate dielectric material is on the first of the gate electrodes, between the metal and the channel region;
a first of the dummy electrodes comprises the metal; and
the gate dielectric material is on the first of the dummy electrodes.

14. The apparatus of claim 13, wherein:
the electrically grounded metal line is in a dielectric layer;
a first of the vias extends through the dielectric layer and contacts the first of the dummy electrodes; and
the first of the vias has a width greater than a thickness of the dielectric layer between the first of the vias and the electrically grounded metal line.

15. The apparatus of claim 14, wherein the plurality of vias comprises more than ten thousand vias on more than ten thousand dummy electrodes.

16. A method, comprising:
establishing a voltage contrast between a plurality of metal contacts and a plurality of dummy electrodes, a plurality of transistor structures comprising the metal contacts on source and drain bodies, the plurality of transistor structures comprising gate electrodes between the source and drain bodies, one or more dielectric layers between the metal contacts and the gate electrodes and between the metal contacts and the dummy electrodes, the plurality of dummy electrodes aligned with the gate electrodes; and
detecting a brightness variation between a coupled one of the dummy electrodes and a floating one of the dummy electrodes, the coupled one of the dummy electrodes coupled to an individual one of the metal contacts by a metal structure shorting through the dielectric layers.

17. The method of claim 16, wherein the establishing the voltage contrast between the plurality of metal contacts and the plurality of dummy electrodes comprises stimulating a plurality of vias with a beam of electrons or ions.

18. The method of claim 17, wherein the establishing the voltage contrast between the plurality of metal contacts and the plurality of dummy electrodes comprises grounding the plurality of metal contacts.

19. The method of claim 17, wherein the detecting the brightness variation between the coupled one of the dummy electrodes and the floating one of the dummy electrodes comprises detecting the brightness variation at an individual one of the vias on the coupled one of the dummy electrodes.

20. The method of claim 16, wherein the plurality of dummy electrodes comprises more than a million dummy electrodes.
